(19) United States
(12) Patent Application Publication
(10) Pub. No.: US 2024/0273246 A1
(43) Pub. Date: Aug. 15, 2024

(54) METHOD OF BOUNDING SPATIAL DATA

(71) Applicant: Siemens Industry Software Inc., Plano, TX (US)

(72) Inventor: Andrew Fitt, Cambridge (GB)

(21) Appl. No.: 18/568,581

(22) PCT Filed: Jun. 17, 2021
(86) PCT No.: PCT/US2021/037766

§ 371 Date: Dec. 8, 2023

(51) Int. Cl. G06F 30/10

(52) U.S. Cl. CPC G06F 30/10

(57) ABSTRACT

A computer-implemented method of bounding spatial data in a hierarchical product structure with hierarchical transforms is described. Initially, the part or part assembly at the lowest level of a hierarchical assembly path is selected. Then, a hierarchical merge of the spatial bounds of one or more bounding boxes of the part or part assembly is performed to generate a set of intermediate spatial bounds. Following this, a merge of the set of oriented bounds of the one or more bounding boxes of the part or part assembly is performed to generate a reduced set of oriented bounds. Finally, the intermediate bounds and the reduced set of oriented bounds are stored for use in configuring the assembly path when building a product from the hierarchical product structure.

The present patent document is a § 371 nationalization of PCT Application Serial No. PCT/US2021/037766, filed Jun. 17, 2021, designating the United States, which is incorporated by reference in its entirety.

### TECHNICAL FIELD

The present disclosure relates to a computer-implemented method of bounding spatial data in a hierarchical product structure with hierarchical transforms, in particular, where the hierarchical product structure includes a product assembly path formed from a plurality of parts and/or part assemblies, each part or part assembly having a parent-child relationship with at least one other part or part assembly within the product assembly path.

### BACKGROUND

Computer Aided Design (CAD) tools are used frequently in the manufacture of complex products. Such products may be represented within the software as a hierarchical product structure, e.g., displayed in the form of a product tree containing a number of assembly paths for various parts and part assemblies within the complex product. This allows a user to interrogate the product structure in a simple manner to view or edit the parts and part assemblies stored within the product structure. Over time these parts and parts assemblies will undergo a number of revisions, which require configuring to produce a buildable product. For example, in automotive manufacture, a wheel requires several wheel bolts to be affixed to an axle. The wheel itself may be a front, rear, left, or right wheel, the axle will be mounted onto the chassis, the chassis linked to a vehicle model, and so on. This represents a fairly short assembly path between the root (e.g., the vehicle) and the final item (e.g., a wheel bolt), but for a fully configured, buildable product, each wheel bolt requires its own assembly path in the hierarchical product structure. The resulting configured product may therefore be sizeable as each assembly path must be configured to achieve the full product structure. Each part or part assembly within the assembly path has a parent-child relationship with at least one other part and/or part assembly. The more complex a product, the longer the assembly path and the greater the number of individual parent-child relationships to manage.

In order to modify, manipulate or make choices about the root product, in this case the vehicle, a user needs to be able to search for occurrences of parts and part assemblies, individual parts or revisions of parts within the product structure. Searching and configuring such a product structure may be slow, depending on the volume of data involved, and may be improved by using a cache of the configured product and its explosion into occurrences of parts and part assemblies. However, a caching approach for such configured products has a number of disadvantages. Firstly, each individual configuration of the product requires a separate cache. Each cache needs to be stored and kept up to date. Secondly, change management processes lead to change-specific, user-specific, and group-specific configurations of a product. This increases the number of caches required. Lastly, historical configurations will also require a separate cache for each history point, no matter how few or many revisions are made. This increases the number of caches required yet further. Alternative approaches include techniques such as database indexing of paths through the product structure, which while an improvement on caching approaches, work well for short time periods. Longer time periods are likely to result in an explosion of paths due to revisions of parts and part assemblies. This may be limited by indexing recent changes over a short time, but this may not be practical or desirable for the user.

A further issue is that each part or part assembly within a product exists within its own local co-ordinate space, which requires a positioning transform to transform the part or part assembly to the global co-ordinate space. For a part or part assembly located a long way down an assembly path, each child part or part assembly must first be transformed to its parent's local co-ordinate space, and so on, until the top of the assembly path is reached. Therefore, the number of positioning transformations required to achieve this will depend on the level of the part or part assembly within the assembly path and the number of positioning transformations associated with each part or part assembly (because there may be more than one). As an example, an eight-level assembly path includes the lowest level of a part with seven levels of other parts or part assemblies hierarchically positioned between the part and a top-level assembly. Assuming that each level has five positioning transforms, relating to various edits during the lifetime of the part, this will require 5⁷ or 78,125 permuted transforms to configure the assembly path when building a product. There exists a need, therefore, to be able to index such hierarchical product structures in such a manner that searching for parts and part assemblies and configuring products may be done without an explosion of data, regardless of the number of revisions carried out to the product or any of its parts.

### SUMMARY

The scope of the present disclosure is defined solely by the appended claims and is not affected to any degree by the statements within this summary. The present embodiments may obviate one or more of the drawbacks or limitations in the related art.

The present disclosure aims to address these issues, by providing, in a first aspect, a computer-implemented method of bounding spatial data in a hierarchical product structure with hierarchical transforms. The hierarchical product structure includes a hierarchical product assembly path formed from a plurality of parts and/or part assemblies, wherein each part or part assembly having a parent-child relationship with at least one other part or part assembly within the product assembly path and forming a level of the assembly path. Each part or part assembly is associated with spatial bounds and oriented bounds within its own co-ordinate space, stored as one or more oriented bounding boxes. Additionally, each part or part assembly is transformed by a positioning transform between its local space and a global space of the product. The method includes: selecting the part or part assembly at the lowest level of an assembly path; performing a hierarchical merge of the spatial bounds of the bounding box(es) of the part or part assembly to generate a set of intermediate bounds; performing a merge of the set of oriented bounds of the part or part assembly to generate a reduced set of oriented bounds; and storing the intermediate bounds and the reduced set of oriented bounds for use in configuring the assembly path when building a product from the hierarchical product structure.

By taking this approach, not only is permutation explosion avoided when applying positioning transforms but bounding box expansion seen with axis-aligned bounding boxes may also be precluded.

The performing of a hierarchical merge may include: querying the set of spatial bounds for the bounding box(es) of the part or part assembly and setting the queried spatial bounds as the current spatial bounds; splitting the assembly path into a series of parent-child hops from the part or part assembly to the top of the assembly path; querying the positioning transforms for the parent-child hop between the part or part assembly and its parent; permuting the positioning transforms with the current spatial bounds; merge the permuted spatial bounds and replacing the current spatial bounds with the merged permuted spatial bounds; and iterating over the assembly path by repeating the querying of the positioning transforms, the permuting of the positioning transforms, and the merging of the permuted spatial bounds for each parent-child hop in the assembly path to generate the set of intermediate bounds.

The performing of a merge of the set of oriented bounds may include: determining the rotations of the oriented bounding boxes of the part or part assembly; partitioning the rotations into groups of similar rotations; for each rotation group: (1) computing a median rotation from the rotation group; (2) obtaining the oriented bounding boxes in the rotation group sharing a common rotation; and (3) re-bounding the oriented bounding boxes and partitioning into groups of similar positions; and for each group of similar positions: (1) merging the re-bounded oriented bounding boxes using the median rotation; and (2) iterating over the assembly path to generate the reduced set of oriented bounds.

Each rotation may be represented as a 3×3 matrix, and the partitioning of the rotations may include converting each matrix element to a point in nine-dimensional space.

The partitioning of the rotations may further include: growing each nine-dimensional point to a nine-dimensional bounding box; partitioning the nine-dimensional bounding box into overlapping groups; and for each overlapping group: (1) determining the nine-dimensional points; (2) converting each nine-dimensional point into a 3×3 rotation matrix; and (3) outputting the 3×3 rotation matrices as a group.

The computing of a median rotation may include, for an overlapping group: computing the minimum nine-dimensional bounding box using the determined nine-dimensional points; determining the median of the nine-dimensional bounding box; converting the nine-dimensional median to a 3×3 median matrix; and normalizing the 3×3 median matrix such that its x, y, z unit vectors map to unit vectors and unit length.

The nine-dimensional bounding box may be axis-aligned in nine-dimensional space.

Applying the median matrix to an oriented bounding box may create a bounding rhomboid. On subsequent iterations, the oriented bounding box may be the minimum bounding rhomboid.

The re-bounding may include: determining the minimum bounding rhomboid in which the oriented bounding box fits; and using the minimum bounding rhomboid to re-bound an oriented bounding box.

The partitioning into groups of similar positions may include transforming a non-axis-aligned bounding box in the local space using a matrix inverse to an axis-aligned bounding box in the inverse space.

Merging the re-bounded oriented bounding boxes may include determining the minimum bounding rhomboid in which all of the re-bounded bounding rhomboids fit.

The 3×3 matrix may be a rigid body matrix or an affine matrix.

Each rotation may be represented as a 3×3 matrix, and the partitioning of the rotations may include converting each matrix to a rotation quaternion.

The present disclosure also provides, in a second aspect, a computer program, which when executed on a data processor, causes the data processor to carry out the method outlined above.

### BRIEF DESCRIPTION OF THE DRAWINGS

The disclosure is now described by way of example only, and with reference to the accompanying drawings in which:

FIG. 1 is a schematic representation of an example of an assembly path in a hierarchical product structure.

FIG. 2 is a flow chart of a method in accordance with an embodiment.

FIGS. 3a and 3b are a schematic representation of an example of an axis-aligned bounding box.

FIGS. 4a and 4b are a schematic representation of an example of a rhomboid bounding box bounding a non-axis-aligned oriented bounding box.

FIG. 5 is a schematic representation of an example of a rhomboid bounding box bounding a group of axis-aligned rhomboid bounding boxes.

### DETAILED DESCRIPTION

Within a hierarchical product structure for a complex product, not only are there are a plurality of product assembly paths formed from a plurality of parts and/or part assemblies, but each part or part assembly is associated with geometrical bounds within its own co-ordinate space. These geometrical bounds include spatial bounds (e.g., operated on by a translation) and oriented bounds (e.g., operated on by a rotation), stored as one or more oriented bounding boxes. As well as each part or part assembly having a parent-child relationship with at least one other part or part assembly within the product assembly path, each part or part assembly is transformed by a positioning transform between its local space and the global space of the product. As described above, for a part or part assembly located a long way down an assembly path, each child part or part assembly must first be transformed to its parent's local co-ordinate space, and so on, until the top of the assembly path is reached. In the embodiments below, an approach is taken to split the geometric bounds of each part or part assembly and deal with the spatial bounds and oriented bounds separately. This is done by initially selecting a part or part assembly at the lowest level of the assembly path. This may be because it requires editing, for example. Then, a hierarchical merge of the spatial bounds of the part or part assembly is performed to generate a set of intermediate bounds. Once this is done, a merge of the set of oriented bounds of the part or part assembly is performed, this time to generate a reduced set of oriented bounds. Finally, the intermediate bounds and the reduced set of oriented bounds are stored for use in configuring the assembly path when building a product from the hierarchical product structure.

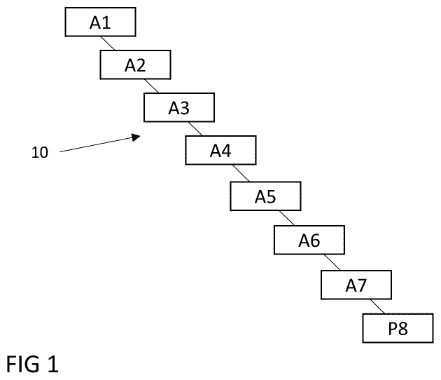

If we consider a complex product that includes a large number of parts and part assemblies, an assembly path is a sequence of items representing possible Bill of Materials (BOM) lines within the product. There will therefore be as many assembly lines as necessary to include all of the items that will need to be configured to build the complex product. FIG. 1 is a schematic representation of an assembly path in a hierarchical product structure. The assembly path 10 includes eight levels, with the top level of the hierarchical assembly path being a part assembly A1. Levels two to seven are successive part assemblies A2, A3, A4, A5, A6, A7, with the lowest level of the hierarchical assembly path being a part P8. The part P8 is located inside the part assembly A7, the part assembly A7 is located inside the part assembly A6 and so on, with the top-level part assembly A1 containing all of the items within the assembly path. Each of the part assemblies A1 to A7 has a parent relationship with either a child part assembly or the child part 8, and conversely the child part 8 and the part assemblies A2 to A7 have a child relationship with a parent part assembly. The relationship between each successive parent-child pair may be described as a “parent-child hop,” whether this is ascending or descending the assembly path 10. Each of the part assemblies A1 to A7, and the part P8, also have their own local co-ordinate spaces, which require the various parts/part assemblies to be positioned using positioning transforms. The part assembly A1 requires a positioning transform to be positioned in the product global space when the hierarchical assembly path 10 is configured to build the product. In an unconfigured hierarchical product structure, there may be more than one positioning transform for the same part, depending on the revision history of the part or part assembly in question.

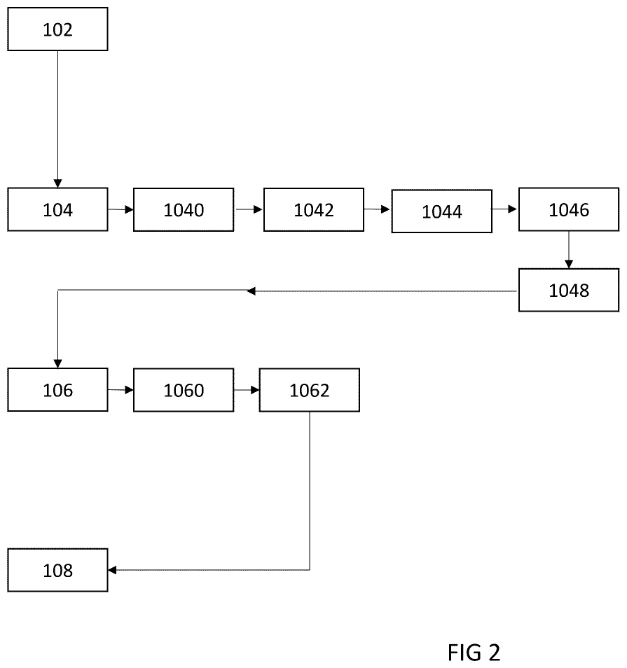

FIG. 2 is a flow chart of a method in accordance with an embodiment. The method is carried out in a data processing system, by a computer program including instructions that, when executed by a data processor in the data processing system, cause the data processor to carry out the method described herein. The method 100 is described with respect to bounding the spatial data for the product P8 using hierarchical transforms. The method 100 may be used to carry out bounding of spatial data using hierarchical transforms for any number of parts and/or part assemblies within a complex product. Therefore, in the following examples, the method 100 may be applied to any part or part assembly, and within any length of hierarchical assembly path 10, regardless of the number of levels in the hierarchical assembly path 10. In the description below, the term “part” may therefore also be read as “part assembly” for the purposes of carrying out the disclosure.

Initially, at act 102, the part or part assembly at the lowest level of an assembly path 10 is selected. The part P8 lies at the lowest level of an eight-level assembly path, where the top level of the assembly path is the part assembly A1. At act 104, a hierarchical merge of the spatial bounds of the bounding box(es) of the part P8 is performed to generate a set of intermediate bounds. By generating a set of intermediate bounds, the combinatorial explosion associated with permuting many positioning transforms is avoided. At act 106, a merge of the set of oriented bounds of the bounding box(es) of the part P8 is performed to generate a reduced set of oriented bounds. The reduced set of oriented bounds contains a reduced number of oriented bounds compared with the total number for the part P8 before merging takes place.

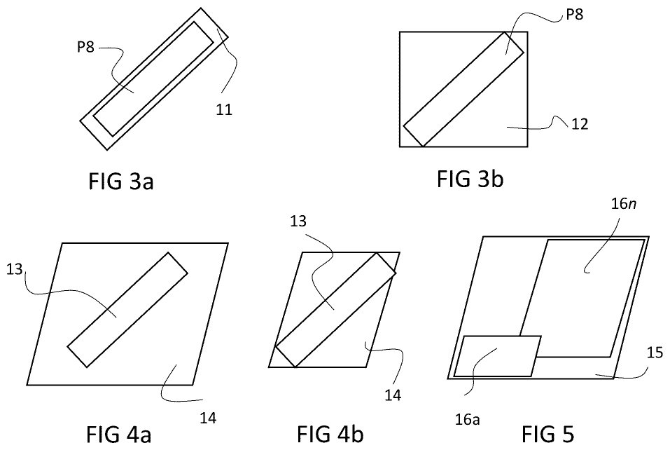

One issue associated with merging oriented bounding boxes is that at each parent-child hop, the merging requires the conversion of the oriented bounding boxes to axis-aligned bounding boxes, which grows the bounding box. This is illustrated in FIGS. 3a and 3b, which are a schematic representation of an axis-aligned bounding box. FIG. 3a shows the part P8 situated in a non-axis-aligned oriented bounding box 11. The dimensions of the non-axis-aligned oriented bounding box 11 are little different to those of the part P8, in order to enclose (bound) the part P8 completely. The long axis of the box for the part P8 lies on the diagonal of the axis-aligned bounding box 12, hence determining the size of bounding box required. However, FIG. 3b shows what happens when the part P8 is placed in an axis-aligned bounding box 12. In order for the axis alignment to occur, the bounding box 12 ends up being much greater in size than the part P8, resulting in a bounding box expansion when compared with the oriented bounding box 11. This expansion may occur at each and every parent-child hop, such that during a hierarchical merge the expansion may quickly become large, unwieldy, and slow, taking up an increased amount of computing resource and becoming less and less useful. It is therefore key to utilize the oriented bounding box approach at this stage rather than the axis-aligned bounding box approach to minimize this unwanted expansion. Finally, at act 108, both the intermediate bounds and the reduced set of oriented bounds are stored for use in configuring the assembly path when building a product from the hierarchical product structure. Storage may take place in memory located internal to the data processing system itself, or externally, such as utilizing cloud services. By storing the resulting intermediate bounds and the reduced set of oriented bounds, these may be called whenever the product is configured. Although each act within the method employs both sorting and scanning, the method in accordance with the embodiments well to large numbers j of input boxes, as O(j·log(j)).

The techniques utilized in the method outlined above are now described in further detail.

### Hierarchical Merge

A hierarchical merge is one where smaller structures such as parts and part assemblies at the lowest level of an assembly path, are merged in hierarchy order until the top level of the assembly path is reached. In the embodiments described herein, the aim of the hierarchical merge is to reduce the number of spatial bounds required to contain the assembly path 10. At act 1040, the set of spatial bounds for the bounding box of the part P8 are queried, and these queried spatial bounds are set as the current spatial bounds. The current spatial bounds are those undergoing an operation at the time. Hence initially, the current spatial bounds are those of the part P8. In order to merge the spatial bounds for all of the entities in the assembly path 10, at act 1042, the assembly path is split into a series of parent-child hops from the part P8 to the top of the assembly path, at the part assembly A1. In this manner, the process starts at the lowest level of the assembly path and works, hierarchically, towards the top level of the assembly path. For each parent-child hop, at act 1044, the positioning transforms for the parent-child hop between the part P8 and its parent A7 are queried. The part P8 may have more than one positioning transform as a result of editing, such as small positioning changes over the lifecycle of the part P8, changes in weight or strength or even component materials.

If a hop at a different level is considered, for example, from a hop between the part assembly A7 at level seven of the assembly path and the part assembly A6 at level six of the assembly, this requires knowledge of the positioning bounds that position the part assembly A7 within the part assembly A6. For the part P8, this is also required for every other part assembly parent-child hop along the hierarchical assembly path 10. At act 1046, these positioning transforms are permuted with the current spatial bounds allocated in act 1040. The resulting permuted bounds are merged in act 1048, and the merge permuted spatial bounds are used to replace the current spatial bounds from act 1040. The process is repeated for each parent-child hop until the top of the assembly path 10 at part assembly A1 is reached, at which point the merged spatial bounds are the final spatial bounds as a result of the hierarchical merge. For an assembly path 10 having n levels, and where each level of the assembly path 10 is associated with m positioning transforms, merging without using the hierarchal merge in accordance with embodiments would result in mⁿ⁻¹ permuted transforms. However, by using the method described above results in m*n−1 intermediate bounds for a completed merge, and a significant saving in both time and computing resource. For the example of the part P8, rather than 78,125 permuted transforms, only 35 intermediate bounds are stored for future product structure configuration.

### Merging Oriented Bounds

As described above, one major advantage of the embodiments is the avoidance of box expansion by using oriented bounding boxes rather than axis-aligned bounding boxes at various stages of the method. An oriented bounding box may be represented as a rotation and a translation, and if a positioning transform is applied to this oriented bounding box, a new oriented bounding box is created. The new oriented bounding box is represented by a new rotation and a translated bounding box. For the initial iteration, the bounding box is an oriented bounding box, but when subsequently iterating along the assembly path, the minimum bounding rhomboid of the previous iteration replaces the bounding box. At act 1060, the rotations of the oriented bounding boxes of the part P8 are determined. To partition by rotation, the rotation itself is represented as a 3×3 matrix, and each matrix element is converted to a point in nine-dimensional space. Each nine-dimensional box is grown into a nine-dimensional bounding box, e.g., using an angular merge tolerance. The nine-dimensional bounding box is partitioned into overlapping groups, as described below.

### Intervals and Interval Partitioning

Taking a simple example of a three-dimensional bounding box and expanding to all nine-dimensions at the end, the bounding box is projected onto the axis direction in order to form a 1-D interval from the 3-D bounding box. For a bounding box [xmin, ymin, zmin; xmax, ymax, zmax], the x interval will be [xmin, xmax], the y interval will be [ymin, ymax] and the z interval [zmin, zmax]. Taking as an example the bounding box:
[0, 0, 0, 10, 3, 1]
   when projected onto the x axis direction gives [0, 10], they axis direction gives [0, 3] and the z axis direction gives [0, 1]. Once the projection has been done, the 1-D intervals [min, max] are sorted into a chosen order. In this example, the 1-D intervals are sorted into ascending order of min. Alternatively, the 1-D intervals may be sorted into descending order of max. Taking the example of the following intervals:
[5, 6], [0, 1], [10, 11], [5, 7]
   these have a possible order of:
[0, 1], [5, 7], [5, 6], [10, 11]
   where the relative ordering of the equal minimum intervals, [5, 6] and [5, 7] is not critical, because this does not affect the end points of the order. Equally, had it been desirable to order the intervals in descending maxima, this would result in an order of:
[10, 11], [5, 7], [5, 6], [0, 1]

Once sorting has been completed, the next stage is to scan the 1-D intervals, in ascending (or descending, as applicable) order, and assign integer partition identifications. Here, overlapping intervals have the same identification. Again, using the ordering based on ascending minimum, the scanning process requires iterating through the 1-D intervals in the sorted order, and tracking the “high-water mark” of the maximum, corresponding to the maximum value of max. So, starting from the sorted list:
[0, 1], [5, 7], [5, 6], [10, 11]

The first interval (having the lowest value of min is [0, 1]. This is assigned a partition identification xpar of 0, and the high-water mark is 1. The next interval is [5, 7], which is above the high-water mark of 1, and therefore is allocated a new partition identification of 1. The new high-water mark is 7. The next interval is [5, 6], which is not above the high-water mark, (as 6 is less than 7) and so is also allocated the partition identification 1. Finally, the interval [10, 11] is above the high-water mark of 7, and so is allocated a new partition identification, 2, and a new high-water mark of 11 is set.

In effect, the sorted intervals are scanned to determine a gap, and whenever a gap is found, a new partition is started. This is the same if the converse method of using descending values of max to order the intervals is used, then a low-water mark (the lowest value of min) is used to allocate the partition identification.

This process is repeated for all of the points in the nine-dimensional space, leading to values of dₙpar being allocated, where dₙpar is the partition identifier of each of n dimensions. Each bounding box is therefore represented by a partition identification nonuplet [d₁par, d₂par, d₃par, d₄par, d₅par, d₆par, d₇par, d₈par, d₉par].

### Overlapping Bounding Boxes

To cope with overlapping bounding boxes and to provide that the bounding boxes may be merged successfully, the intervals may be modified to increase or decrease the number of bounding boxes having the same partition identification nonuplet. This may be by the intervals being expanded, contracted, or transformed. Again, using a simpler tuple as an example, take the two bounding boxes:
i) [1, 1, 1, 1.99999999, 2, 2]
ii) [2, 1, 1, 3, 2, 2]

The bounding boxes have a small (0.00000001) gap between them in the x axis direction. Partitioning slightly different bounding boxes to the originals will enable control of the grouping. This may be to allow merging of bounding boxes where there is a 10% gap, or to avoid merging bounding boxes with a 10% overlap, for example. Taking bounding boxes vii) and viii) and expanding 10% in each direction would give:
iv)′ [0.90000001, 0.9, 0.9, 2.099999989, 2.1, 2.1]
v)′ [1.9, 0.9, 0.9, 3.1, 2.1, 2.1]

These altered bounding boxes now overlap and have partition identification tuples of (0, 0, 0) and (0, 0, 0). Merging the original boxes results in a single box [1, 1, 1, 3, 2, 2]. Hence, if merging bounding boxes where there is a gap of n %, the intervals are expanded by n % before assigning partition identification. If there is a numerical imprecision or tolerance, the intervals are expanded by an amount corresponding imprecision or tolerance.

At act 1062, the rotations determined in act 1060 are partitioned into groups of similar rotations. For each rotation group, a median rotation is computed, the oriented bounding boxes in the rotation group sharing a common rotation are obtained and the oriented bounding boxes are re-bounded and partitioned into groups of similar positions. For each group of similar positions, the re-bounded oriented bounding boxes are merged using the median rotation. Each merged box is output to generate the reduced set of oriented bounds. When expanding this technique to nine dimensions, each point in nine-dimensional space may be represented as a sequence of nine integers. These sequences of integers may be sorted in point order to pull together matching integers, indicating which sequences to merge.

### Median Rotation of a Set of Rotations

The median rotation of each overlapping group of rotations is obtained from nine-dimensional space using the nine-dimensional mid-point. Using the determined nine-dimensional points, the minimum nine-dimensional bounding box is computed. This will be axis-aligned in nine-dimensional space. The median (mid-point) of the nine-dimensional bounding box is determined and converted to a 3×3 median matrix. This median matrix may be normalized such that its x, y, z unit vectors map to unit vectors and hence unit length. While the median matrix is close to a rotation matrix, it may contain a small amount of skew. When applied to a bounding box, the median matrix will transform the bounding box into a bounding rhomboid or skew bounding box. The normalization act may allocate the resulting 3×3 matrix responsibilities for rotation, reflection, and skew, and also keep the responsibility for translation and scale with the bounding box. In some cases, the median matrix may contain a large amount of skew or fail to normalize. This may be a sign that the angular merge tolerance used to create the nine-dimensional bounding box was too large and applied to a broad spread of rotations. In this situation, the median matrix may be set to the identity matrix, which results in a simple, fast, and robust solution, although other strategies may be used if desired. The bounding rhomboid is therefore an oriented, non-axis-aligned, bounding box volume.

### Re-Bounding to a Given Orientation

Re-bounding to a given orientation is illustrated in FIGS. 4a and 4b, which are a schematic representation of a rhomboid bounding box bounding a non-axis-aligned oriented bounding box. This is the process of taking the merged bounding box, which in the first iteration will be a non-axis-aligned, oriented bounding box, and creating a new set of spatial bounds without the unnecessary box expansion that occurs with repeated merges of oriented or axis-aligned bounding boxes. As described above, the application of the median matrix creates a rhomboid bounding box. In FIG. 4a, an original oriented bounding box 13 is itself bounded by a rhomboid bounding box 14. To avoid unnecessary box expansion, it is necessary to determine the minimum bounding rhomboid 14 in which the oriented bounding box 13 fits. This is illustrated in FIG. 4b, where the bounding rhomboid has been shrunk such that it contacts the four corners of the original bounding box 13, hence the minimum bounding rhomboid is used to re-bound an oriented bounding box. This may be done by applying a matrix inverse to the median matrix and minimum and maximum boundaries to the rhomboid bounding box 14. While in the first iteration of the merging process the re-bounding is applied to an oriented bounding box, on subsequent iterations the minimum bounding rhomboid is used as oriented bounding box.

### Partitioning by Position Given a Common Rotation

Partitioning by position given a common rotation involves transforming a non-axis-aligned bounding box in the local space using a matrix inverse to an axis-aligned bounding box in the inverse space. This may be done by using the partitioning using an irregular grid technique described below.

### Partitioning Using an Irregular Grid

Once the partition identifications as described above have been allocated and the bounding boxes are represented by partition identification nonuplets, it is necessary to partition the bounding boxes by the partition identification nonuplet. As a simple example, this is illustrated in three dimensions below by the three bounding boxes:
i) [0, 0, 0, 10, 10, 10]
ii) [5, 15, 0, 15, 25, 10]
iii) [5, 0, 0, 15, 10, 10]

These bounding boxes have x partition identifications xpar: 0, 0 and 0, y partition identifications ypar: 0, 1, 0 and z partition identifications zpar: 0, 0 and 0. This results in the following partition identifications:
xpar: 0 0 0
ypar: 0 1 0
zpar: 0 0 0 and therefore, the following partition identification tuples:
iii) (0, 0, 0)
iv) (0, 1, 0)
v) (0, 0, 0)

These partition identification tuples are then sorted in a lexicographical order in order to group identical tuples together: i) and iii) together, ii) alone. The choice of sort condition is not important as long as the sort condition is consistent. For example, we could sort by xpar, then ypar for equal xpar, then zpar for equal xpar and ypar. This will group equal (xpar, ypar, zpar) values together. Using an irregular grid approach effectively results in an irregular-sized grid is formed around the bounding boxes, such that each plane in the grid touches at least one bounding box but does not intersect with any of the bounding boxes. Each bounding box occupies exactly one grid cell, and each occupied cell has a partition identification tuple label (xpar, ypar, zpar). An individual interval scan is therefore equivalent to scanning a plan in each of the x, y, and z axis directions. This is therefore extended to the nine directions of the nine-dimensional space.

### Merging Bounds Given a Common Rotation

FIG. 5 is a schematic representation of a rhomboid bounding box bounding a group of axis-aligned rhomboid bounding boxes. To merge a group of bounds with the same orientation, a similar approach to re-bounding may be taken. The minimum bounding rhomboid 15 in which all of the re-bounded bounding rhomboids 16a . . . 16n fit is determined. The bounding rhomboid 15 has been shrunk such that it contains all of the minimum bounding rhomboids 16a . . . 16n, which may be done as in the case of a single bounding rhomboid 14 above, by applying a matrix inverse to the median matrix and minimum and maximum boundaries to the bounding rhomboid 15.

The embodiments described above resulting in a bounding rhomboid are particularly suited to situations where transform data is stored as a rotation matrix. Wherever possible, the rotation matrix data is untouched, and the method 100 is particularly tolerant of unusual or unexpected conditions in the rotation matrix data. Each of the oriented bounding boxes in each of the acts described above may be a rhomboid bounding box, it is not necessary to restrict this format to the final stages of the method. While in the examples above the 3×3 matrix is a rigid body matrix, it may alternative be an affine matrix, such as a reflection, skew, or scale matrix, because all of these map a rhomboid bound to a rhomboid bound. As an alternative to using a nine-dimensional space, each matrix may be converted to a rotation quaternion, such that the median matrix becomes a four-dimensional median quaternion. Rather than representing the 3×3 matrix in nine-dimensional space, for a rotation matrix or a translation matrix the quaternion format removes most of the duplication within the matrix resulting in a four-dimensional array. Any matrix in which there is a skew component would however be unsuitable for conversion to quaternion format. While it is possible to convert between the quaternion and nine-dimensional formats and vice versa, this may result in a loss of information and a loss of method stability. However, by extending the techniques above to work in four dimensions, any geometric information that has been provided by a user in quaternion format may be processed in that format to avoid conversion losses. For example, when expanding merge technique to four dimensions, each point in four-dimensional space may be represented as a sequence of four integers. These sequences of integers may be sorted in point order to pull together matching integers, indicating which sequences to merge. Again, it may be desirable to normalize this to unit length, such that the scaling factor is 1.0.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method of bounding spatial data in a hierarchical product structure with hierarchical transforms, the hierarchical product structure comprising a hierarchical product assembly path formed from a plurality of parts and/or part assemblies, wherein each part or part assembly of the plurality of parts and/or part assemblies comprises a parent-child relationship with at least one other part or part assembly of the plurality of parts and/or part assemblies within the hierarchical product assembly path and forms a level of the hierarchical product assembly path, wherein each part or part assembly is associated with spatial bounds and oriented bounds within a coordinate space of the respective part or part assembly, stored as one or more oriented bounding boxes, and wherein each part or part assembly is transformed by a positioning transform between local space of the respective part or part assembly and a global space of the product, the method comprising:
selecting the part or part assembly at a lowest level of an assembly path;
performing a hierarchical merge of the spatial bounds of the part or part assembly to generate a set of intermediate bounds;
performing a merge of the set of oriented bounds of the one or more oriented bounding boxes of the part or part assembly to generate a reduced set of oriented bounds; and
storing the intermediate bounds and the reduced set of oriented bounds for use in configuring the assembly path when building a product from the hierarchical product structure.

2. The method of claim 1, wherein the performing of the hierarchical merge comprises:
querying the set of spatial bounds for the one or more oriented bounding boxes of the part or part assembly and setting the queried spatial bounds as a current spatial bounds;
splitting the assembly path into a series of parent-child hops from the part or part assembly to a top of the assembly path;
querying the positioning transforms for the parent-child hop between the part or part assembly and its parent;
permuting the positioning transforms with the current spatial bounds to provide a permuted spatial bounds;
merging the permuted spatial bounds and replacing the current spatial bounds with the merged permuted spatial bounds; and
iterating over the assembly path by repeating the querying of the positioning transforms, the permuting of the positioning transforms, and the merging of the permuted spatial bounds for each parent-child hop in the assembly path to generate the set of intermediate bounds.

3. The method of claim 1, wherein the performing of the merge of the set of oriented bounds comprises:
determining rotations of the one or more oriented bounding boxes of the part or part assembly;
partitioning the rotations into groups of similar rotations;
for each rotation group:
computing a median rotation from the respective rotation group;
obtaining the one or more oriented bounding boxes in the respective rotation group sharing a common rotation; and
re-bounding the one or more oriented bounding boxes and partitioning into groups of similar positions; and
for each group of similar positions:
merging the one or more re-bounded oriented bounding boxes using the median rotation; and
iterating over the assembly path to generate the reduced set of oriented bounds.

4. The method of claim 3, wherein each rotation is represented as a 3×3 matrix, and
wherein the partitioning of the rotations comprises converting each matrix element to a point in nine-dimensional space.

5. The method of claim 4, wherein the partitioning of the rotations further comprises:
growing each nine-dimensional point to a nine-dimensional bounding box;
partitioning the nine-dimensional bounding box into overlapping groups; and
for each overlapping group:
determining the nine-dimensional points;
converting each nine-dimensional point into a 3×3 rotation matrix; and
outputting the 3×3 rotation matrices as a group.

6. The method of claim 5, wherein the computing of the median rotation comprises, for an overlapping group:
computing the minimum nine-dimensional bounding box using the determined nine-dimensional points;
determining the median of the nine-dimensional bounding box;
converting the nine-dimensional median to a 3×3 median matrix; and
normalizing the 3×3 median matrix such that x, y, z unit vectors of the 3×3 median matrix map to unit vectors and unit length.

7. The method of claim 6, wherein the nine-dimensional bounding box is axis-aligned in nine-dimensional space.

8. The method of claim 6, wherein applying the 3×3 median matrix to an oriented bounding box creates a bounding rhomboid.

9. The method of claim 8, wherein the re-bounding of the one or more oriented bounding boxes comprises:
determining a minimum bounding rhomboid in which an oriented bounding box of the one or more oriented bounding boxes fits; and
using the minimum bounding rhomboid to re-bound the oriented bounding box.

10. The method of claim 9, wherein, in subsequent iterations, the oriented bounding box is the minimum bounding rhomboid.

11. The method of claim 9, wherein the partitioning into the groups of similar positions comprises:
transforming a non-axis-aligned bounding box in the local space using a matrix inverse to an axis-aligned bounding box in the inverse space.

12. The method of claim 11, wherein the merging of the re-bounded oriented bounding boxes comprises determining the minimum bounding rhomboid in which all of the re-bounded bounding rhomboids fit.

13. The method of claim 4, wherein the 3×3 matrix is a rigid body matrix or an affine matrix.

14. The method of claim 3, wherein each rotation is represented as a 3×3 matrix, and
wherein the partitioning of the rotations comprises converting each matrix to a rotation quaternion.

15. A computer program, which when executed on a data processor, causes the data processor to:
select a part or part assembly at the lowest level of an assembly path from a plurality of parts and/or part assemblies that form a hierarchical product assembly path, wherein each part or part assembly of the plurality of parts and/or part assemblies comprises a parent-child relationship with at least one other part or part assembly of the plurality of parts and/or part assemblies within the hierarchical product assembly path and forms a level of the hierarchical product assembly path, wherein each part or part assembly is associated with spatial bounds and oriented bounds within a coordinate space of the respective part or part assembly, stored as one or more oriented bounding boxes, and wherein each part or part assembly is transformed by a positioning transform between local space of the respective part or part assembly and a global space of the product;
perform a hierarchical merge of the spatial bounds of the part or part assembly to generate a set of intermediate bounds,
perform a merge of the set of oriented bounds of the bounding box(es) of the part or part assembly to generate a reduced set of oriented bounds, and
store the intermediate bounds and the reduced set of oriented bounds for use in configuring the assembly path when building a product from the hierarchical product structure.
